(19) United States
(12) Patent Application Publication
(10) Pub. No.: US 2025/0006716 A1
(43) Pub. Date: Jan. 2, 2025

(54) DISPLAY DEVICE

(71) Applicant: CARUX TECHNOLOGY PTE. LTD., SINGAPORE (SG)

(72) Inventors: Shun-Yu Chang, Tainan (TW); Wei-Hsuan Lee, Tainan (TW); Li-Wei Sung, Tainan (TW); Zhi-Wei Lin, Tainan (TW)

(73) Assignee: CARUX TECHNOLOGY PTE. LTD., SINGAPORE (SG)

(21) Appl. No.: 18/666,869

(22) Filed: May 17, 2024

(30) Foreign Application Priority Data
Jun. 30, 2023 (CN) 202310795731.9

(51) Int. Cl. H01L 25/16; H01L 33/58

(52) U.S. Cl. CPC H01L 25/167; H01L 33/58

(57) ABSTRACT

A display device including a display module and a backlight module is provided. The display module has a display region. The backlight module is overlapped with the display module and includes a plurality of light emitting diodes. The plurality of light emitting diodes form a light emitting region. The light emitting region is overlapped with the display region, and an area of the light emitting region is larger than an area of the display region.

### CROSS-REFERENCE TO RELATED APPLICATION

This application claims the priority benefit of China application serial no. 202310795731.9, filed on Jun. 30, 2023. The entirety of the above-mentioned patent application is hereby incorporated by reference herein and made a part of this specification.

### BACKGROUND

### Technical Field

The disclosure relates to an electronic device, in particular to a display device.

### Description of Related Art

In the existing display device, the arrangement of light emitting elements leads to the problem of surrounding dark regions or uneven brightness of the backlight module, which negatively affects the display quality.

### SUMMARY

The disclosure provides a display device, which helps to improve the problem of surrounding dark regions or uneven brightness.

According to an embodiment of the disclosure, the display device includes a backlight module and a display module. The display module has a display region. The backlight module is overlapped with the display module and includes a plurality of light emitting diodes. The plurality of light emitting diodes form a light emitting region. The light emitting region is overlapped with the display region, and an area of the light emitting region is larger than an area of the display region.

In order to make the above-mentioned features and advantages of the disclosure more comprehensible, the following specific embodiments are described in detail with accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 and FIG. 2 are respectively a partial top view and a schematic cross-sectional view of a display device according to the first embodiment of the disclosure.

FIG. 3 is a schematic partial top view of a display device according to the second embodiment of the disclosure.

FIG. 4 is a schematic partial top view of a display device according to the third embodiment of the disclosure.

FIG. 5 and FIG. 6 are respectively a partial top view and a schematic cross-sectional view of a display device according to the fourth embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numerals are used in the drawings and descriptions to refer to the same or like parts.

Certain terms may be used throughout the disclosure and the appended claims to refer to specific elements. Persons skilled in the art should understand that electronic device manufacturers may refer to the same elements by different names. The disclosure does not intend to distinguish between elements that have the same function but have different names. In the following description and appended claims, words such as “comprising” and “including” are open-ended words, so they should be interpreted as meaning “including but not limited to . . . ”.

Directional terms mentioned in the disclosure, such as “up,” “down,” “front,” “back,” “left,” and “right,” merely refer to directions in the accompanying drawings. Accordingly, the directional terms are used to illustrate rather than to limit the disclosure. In the accompanying drawings, each of the drawings illustrates general features of methods, structures, and/or materials used in a particular embodiment. However, the drawings shall not be interpreted as defining or limiting the scope or nature covered by the embodiments. For example, the relative sizes, thicknesses, and positions of layers, regions, and/or structures may be reduced or enlarged for clarity.

A structure (or a layer, an element, a substrate) described in this disclosure being positioned on/over another structure (or a layer, an element, a substrate) may mean that two structures are adjacent and directly connected, or may mean that the two structures are adjacent but not directly connected. Not being directly connected means that at least one intermediate structure (or an intermediate layer, an intermediate element, an intermediate substrate, an intermediate spacing) is between two structures, a lower surface of a structure is adjacent to or directly connected to an upper surface of the intermediate structure, an upper surface of another structure is adjacent to or directly connected to a lower surface of the intermediate structure. The intermediate structure may comprise a single-layer or multi-layer physical structure or non-physical structure, and is not limited thereto. In the disclosure, when a certain structure is disposed “on” other structures, it may mean that the certain structure is “directly” on other structures, or that the certain structure is “indirectly” on other structures, that is, at least one structure is also interposed between the certain structure and other structures.

The terms “about”, “equal”, “the same” or “identical”, “substantially” or “approximately” are generally interpreted as within 20% of a given value or range, or interpreted as within 10%, 5%, 3%, 2%, 1%, or 0.5% of the given value or range. In addition, the phrases “the range is from the first value to the second value” and “the range is between the first value to the second value” mean that the range includes the first value, the second value, and other values in between.

The ordinal numbers used in the specification and the appended claims, such as “first” and “second” are used to modify elements, which do not imply or represent that the (or these) elements have any previous ordinal numbers, nor do they represent the order of a certain element with another element, or the order of a manufacturing method. The use of these ordinal numbers is merely to clearly distinguish an element with a certain designation from another element with the same name. The same terms may not be used in the appended claims and the description. Accordingly, the first component in the description may be the second component in the appended claims.

The electrical connection or coupling described in this disclosure may refer to direct connection or indirect connection. In the case of direct connection, two terminals of elements of a circuit are directly connected or connected via conductive line segment. In the case of indirect connection, switches, a diodes, capacitors, inductors, resistors, other suitable elements, or a combination of the above elements are between the two terminals of the elements of the circuit, but not limited thereto.

In this disclosure, the thickness, length, and width may be measured by an optical microscope (OM), and the thickness or width may be measured from a cross-sectional image in an electron microscope, but not limited thereto. In addition, any two values or directions used for comparison may have certain errors. In addition, the terms “substantially” or “approximately” mentioned in the disclosure generally mean falling within 10% of a given value or range. In addition, the phrases “the given range is from the first value to the second value”, “the given range falls within a range from the first value to the second value” or “the given range is between the first value to the second value” mean that the ranges include the first value, the second value, and other values in between. If a first direction is perpendicular to a second direction, the angle between the first direction and the second direction may be between 80 degrees and 100 degrees; if the first direction is parallel to the second direction, the angle between the first direction and the second direction may be between 0 degrees and 10 degrees.

Unless otherwise defined, all terms (including technical and scientific terms) used herein have the same meaning as commonly understood by persons of ordinary skill in the art to which this disclosure belongs. It should be understood that these terms, such as those defined in commonly used dictionaries, should be interpreted as having a meaning consistent with the related technology and the background or context of the disclosure, and should not be interpreted in an idealized or overly formal manner, unless otherwise specified in the embodiments of the disclosure.

In this disclosure, an electronic device may include a display device, a backlight device, an antenna device, a sensing device, or a splicing device, but not limited thereto. The electronic device may be a bendable or flexible electronic device. The display device may be a non-self-illuminating display device or a self-illuminating display device. The display device may, for example, include liquid crystal, light emitting diode, fluorescence, phosphor, quantum dot (QD), other suitable display media, or a combination of the aforementioned. The antenna device may include, for example, a frequency selective surface (FSS), a radio frequency filter (RF-Filter), a polarizer, a resonator, or an antenna, and the like. The antenna may be a liquid crystal type antenna or a non-liquid crystal type antenna. The sensing device may be a sensing device for sensing capacitance, light, heat, or ultrasonic, but not limited thereto. In the disclosure, an electronic device may include an electronic element, and the electronic element may include a passive component and an active component, such as capacitors, resistors, inductors, diodes, transistors, and the like. Diodes may include light emitting diodes or photodiodes. The light emitting diode may, for example, include an organic light emitting diode (OLED), a mini LED, a micro LED, or a quantum dot LED, but not limited thereto. The splicing device may be, for example, a display splicing device or an antenna splicing device, but is not limited thereto. It should be noted that the electronic device may be any arrangement and combination of the aforementioned, but not limited thereto. In addition, a shape of the electronic device may be rectangular, circular, polygonal, a shape with a curved edge, or other suitable shapes. The electronic device may have peripheral systems such as a drive system, a control system, and a light source system to support a display device, an antenna device, a wearable device (such as augmented reality or virtual reality), a vehicle-mounted device (such as a car windshield), or a splicing device.

It should be noted that in the following embodiments, without departing from the spirit of the disclosure, features in several different embodiments may be replaced, reorganized, and mixed to complete other embodiments. As long as the features of the various embodiments do not violate the spirit of the disclosure or conflict, they may be mixed and matched arbitrarily.

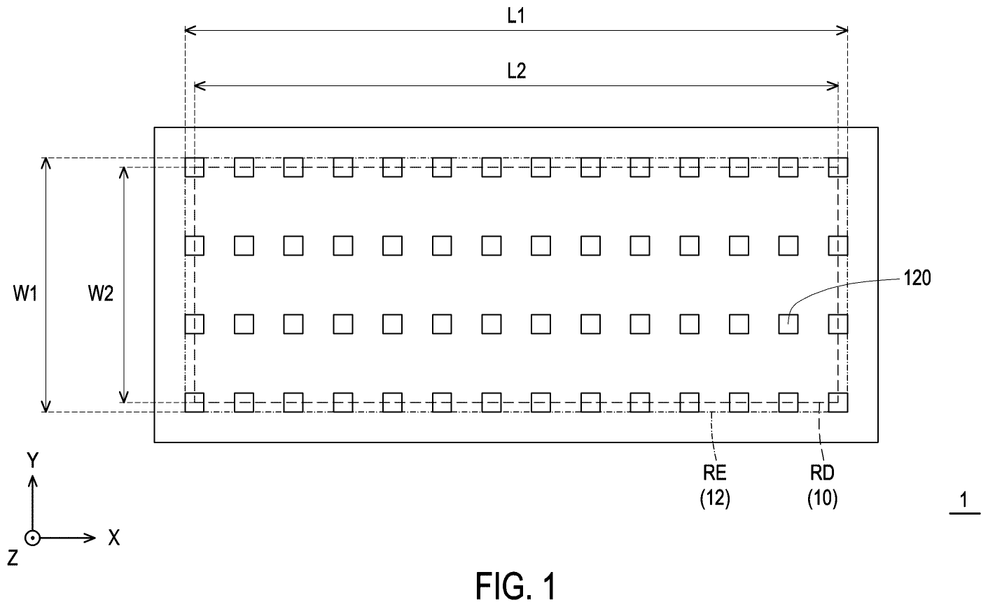

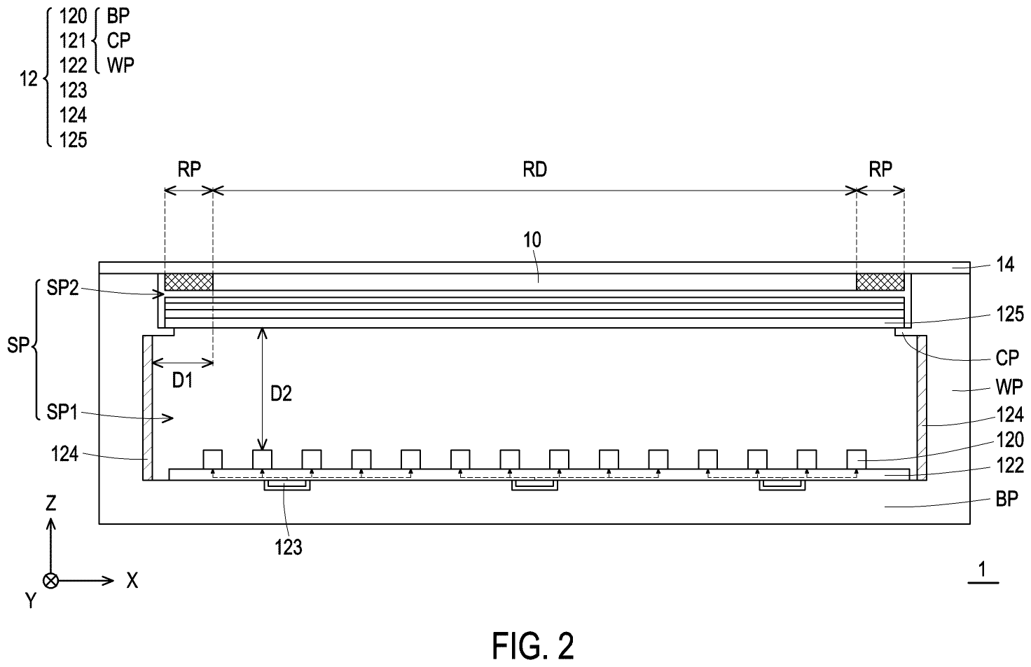

FIG. 1 and FIG. 2 are respectively a partial top view and a schematic cross-sectional view of a display device according to the first embodiment of the disclosure. Please refer to FIG. 1 and FIG. 2. A display device 1 may include a display module 10 and a backlight module 12. The display module 10 has a display region RD. The backlight module 12 is overlapped with the display module 10 and includes a plurality of light emitting diodes 120. The plurality of light emitting diodes 120 form a light emitting region RE. The light emitting region RE is overlapped with the display region RD, and an area of the light emitting region RE is larger than an area of the display region RD.

In detail, the display module 10 may be a non-self-illuminating display module, such as a liquid crystal display module, but not limited thereto. The display region RD of the display module 10 is a region of the display module 10 to provide a displayed image. Although not shown, the display region RD may include a plurality of pixels and a color filter layer, but not limited thereto. The plurality of pixels may be arranged in an array along a direction X and a direction Y, and the color filter layer is overlapped with the plurality of pixels in a direction Z.

In addition to the display region RD, as shown in FIG. 2, the display module 10 may also have a peripheral region RP, and the peripheral region RP may be positioned on at least one side of the display region RD. In some embodiments, the peripheral region RP may surround the display region RD, but not limited thereto. The peripheral region RP of the display module 10 is an area other than the display region RD. Although not shown, the peripheral region RP may include a plurality of routing lines and peripheral lines.

The backlight module 12 is overlapped with the display module 10 in a thickness direction (such as the direction Z) of the display device 1. As shown in FIG. 2, the backlight module 12 may be a direct backlight module, and the backlight module 12 may be disposed below the display module 12, in which the display region RD of the display module 10 is overlapped with a plurality of light emitting diodes 120 of the backlight module 12 in the direction Z, so that the display region RD may receive beams emitted from the plurality of light emitting diodes 120 and convert the beams into a display beam with display information (e.g. gray scale, color).

The plurality of light emitting diodes 120 may be arranged in an array along the direction X and the direction Y. In some embodiments, a light emitting angle of the light emitting diode 120 may be between 110 degrees and 160 degrees, that is, 110 degrees=the light emitting angle ≤160 degrees, but not limited thereto. In some embodiments, a brightness directly above the light emitting diode 120 (the zenith angle is 0 degrees) is smaller than a brightness at the zenith angle of 30 degrees to 70 degrees, but not limited thereto. In some embodiments, a maximum brightness of the light emitting diode 120 is at the zenith angle of 55 degrees to 80 degrees, but not limited thereto.

A largest rectangle surrounded by the plurality of light emitting diodes 120 defines the light emitting region RE. In FIG. 1, the light emitting region RE is marked with a dashed line with dots, and the display region RD is marked with a dashed line. As shown in FIG. 1, the light emitting region RE and the display region RD are overlapped in the direction Z, and an area of the light emitting region RE is larger than an area of the display region RD. FIG. 1 schematically shows that the four edges of the light emitting region RE expand outward from the four edges of the display region RD respectively, that is, each of the plurality of light emitting diodes 120 on the four edges of the light emitting region RE is at least partially positioned outside of the display region RD, but the disclosure is not limited thereto. In other embodiments, although not shown, each of the plurality of light emitting diodes 120 at at least one edge may be completely positioned outside of the display region RD, completely positioned within the display region RD, or positioned partially within the display region RD and positioned partially outside of the display region.

By making an area of the light emitting region RE larger than an area of the display region RD, the brightness of the edge region can be improved, and thus help improve the problem of surrounding dark regions or uneven brightness. In some embodiments, the difference between a length L1 of the light emitting region RE and a length L2 of the display region RD (for example, L1-L2) may be greater than 0 and smaller than or equal to 10 mm, so as to increase the brightness uniformity to more than 50%, such as 50% to 90%. In some embodiments, the difference between a width W1 of the light emitting region RE and a width W2 of the display region RD (for example, W1-W2) may be greater than 0 and smaller than 10 mm, so as to increase the brightness uniformity to more than 50%, such as 50% to 90%.

According to different requirements, the backlight module 12 may further include other elements or film layers. For example, as shown in FIG. 2, the backlight module 12 may further include a back plate 121, a circuit board 122, a chip 123, a reflection sheet 124, and an optical film sheet 125, but not limited thereto.

The back plate 121 is configured to accommodate the display module 10, the plurality of light emitting diodes 120, the circuit board 122, the chip 123, the reflection sheet 124, and the optical film sheet 125. For example, the material of the back plate 121 may include metal, alloy, plastic, or a combination thereof.

The back plate 121 includes a bottom portion BP, a side wall portion WP, and a carrying portion CP, in which the side wall portion WP is connected to the bottom BP, and the carrying portion CP is positioned above the bottom BP and extends from the side wall portion WP toward the center of the back plate 121, so that the accommodating space SP of the back plate 121 is divided into a lower space SP1 and an upper space SP2 by the carrying portion CP, and the lower space SP1 is positioned between the upper space SP2 and the bottom BP.

The circuit board 122 is disposed on the bottom BP of the back plate 121 and positioned in the lower space SP1, and the plurality of light emitting diodes 120 are disposed on the circuit board 122 and electrically connected to the chips 123 positioned between the circuit board 122 and the bottom BP of the back plate 121 through the circuit board 122. Three chips 123 are schematically shown in FIG. 2, and electrical signal transmission paths between the chips 123 and the corresponding light emitting diodes 120 are shown by dashed line arrows. However, it should be understood that the number of the chips 123 and the relative disposition relationship, the number of connections, the electrical signal transmission paths, etc. between the chips 123 and the plurality of light emitting diodes 120 may be changed according to actual requirements.

The reflection sheet 124 is disposed on the side wall portion WP of the back plate 121 to reflect a light beam so that the light beam passes toward the display module 10. The material of the reflection sheet 124 may include metal, alloy, high reflection paint (such as white paint), or a combination thereof, but not limited thereto. In some embodiments, a maximum lateral distance D1 between the reflection sheet 124 and the display region RD of the display module 10 is, for example, from 1 mm to 10 mm, so as to reduce the possibility of light leakage caused by the reflected light.

The optical film sheet 125 is disposed on the carrying portion CP and positioned in the upper space SP2. In addition, the optical film sheet 125 may maintain a proper light mixing distance D2 in the direction Z with the plurality of light emitting diodes 120 through the carrying portion CP. The light mixing distance may vary depending on design parameters/specifications such as the thickness of the backlight module 12, the arrangement of the plurality of light emitting diodes 120, the brightness, the brightness uniformity, and is not limited thereto.

FIG. 2 schematically shows four optical film sheets 125 stacked in the direction Z. However, it should be understood that the number and types of the optical film sheet 125 may be changed according to actual requirements. For example, the optical film sheet 125 may be selected from a diffusion sheet or a prism sheet, but not limited thereto.

According to different requirements, the display device 1 may further include other elements or film layers. For example, as shown in FIG. 2, the display device 1 may further include a cover plate 14. The cover plate 14 is disposed on the side wall portion WP of the back plate 121 and covers the display module 10. The material of the cover plate 14 includes, for example, glass, quartz, ceramics, sapphire, or plastic, but not limited thereto. Plastics may include polycarbonate (PC), polyimide (PI), polypropylene (PP), polyethylene terephthalate (PET), other suitable flexible material, or a combination of the aforementioned materials, but not limited thereto.

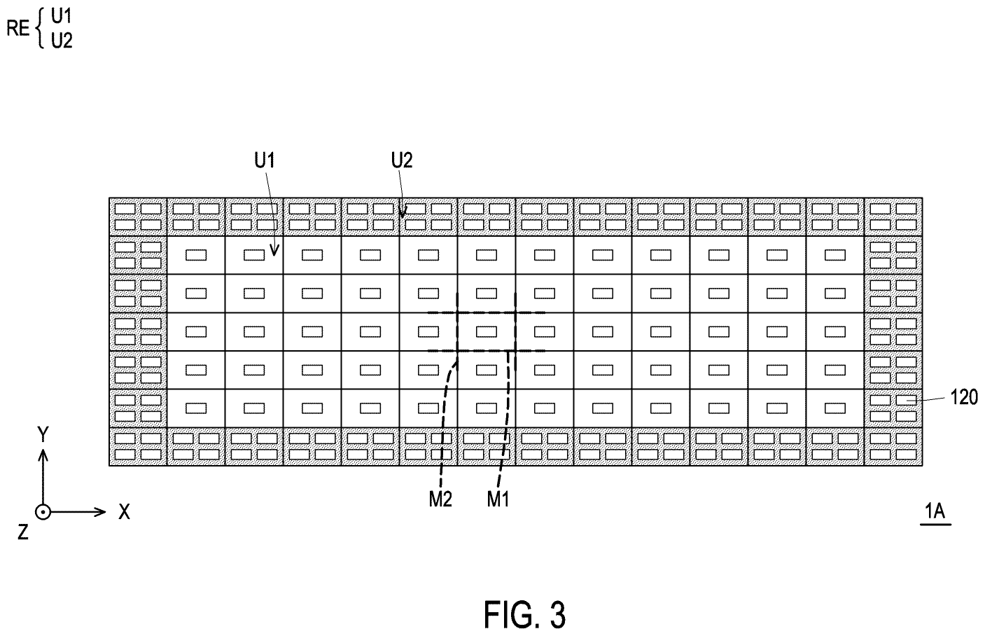

FIG. 3 is a schematic partial top view of a display device according to the second embodiment of the disclosure. For the brevity of the drawings, FIG. 3 only schematically shows the plurality of light emitting diodes 120 and omits other components. Please refer to FIG. 3. The main difference between a display device 1A and the display device 1 in FIG. 1 lies in the arrangement of the plurality of light emitting diodes 120.

In detail, in the display device 1A, the light emitting region RE includes a first unit region U1 and a second unit region U2, and an area of the first unit region U1 is equal to an area of the second unit region U2. In order to distinguish conveniently, the second unit region U2 is represented by dotted shading, while the first unit region U1 is represented by blank shading. Although not shown, the first unit region U1 and the second unit region U2 may be defined by crossed wires (such as signal wires, common electrode wires, or power wires), barriers, or marking lines. On the other hand, when the light emitting region RE lacks partition elements to define the unit region, two midlines M1 extending along the direction X and two midlines M2 extending along the direction Y may be shown from the plurality of light emitting diodes 120 at the central region of the light emitting region RE, in which, each of the midlines M1 is positioned in the middle of two adjacent light emitting diodes 120 arranged along the direction Y, and each of the midlines M2 is positioned in the middle of two adjacent light emitting diodes 120 arranged along the direction X, and the two midlines M1 and the two midlines M2 intersect to define the unit regions.

By controlling the density of the light emitting diodes 120 in different unit regions, the problem of surrounding dark regions or uneven brightness can be improved. Taking FIG. 3 as an example, the light emitting region RE may include the plurality of first unit regions U1 and the plurality of second unit regions U2, and the plurality of second unit regions U2 may surround the plurality of first unit regions U1. Under this architecture, the density of the light emitting diodes 120 of the second unit regions U2 may be greater than the density of the light emitting diodes 120 of the first unit regions U1, so as to increase the brightness of the edge region, thus the problem of surrounding dark regions or uneven brightness can be improved. In the disclosure, the density of the light emitting diodes in the unit region refers to an area occupied by the light emitting diodes in the unit region. The larger the area occupied by the light emitting diodes in the unit region, the greater the density of the light emitting diodes in the unit region; conversely, the smaller the area occupied by the light emitting diodes in the unit region, the smaller the density of the light emitting diodes in the unit region.

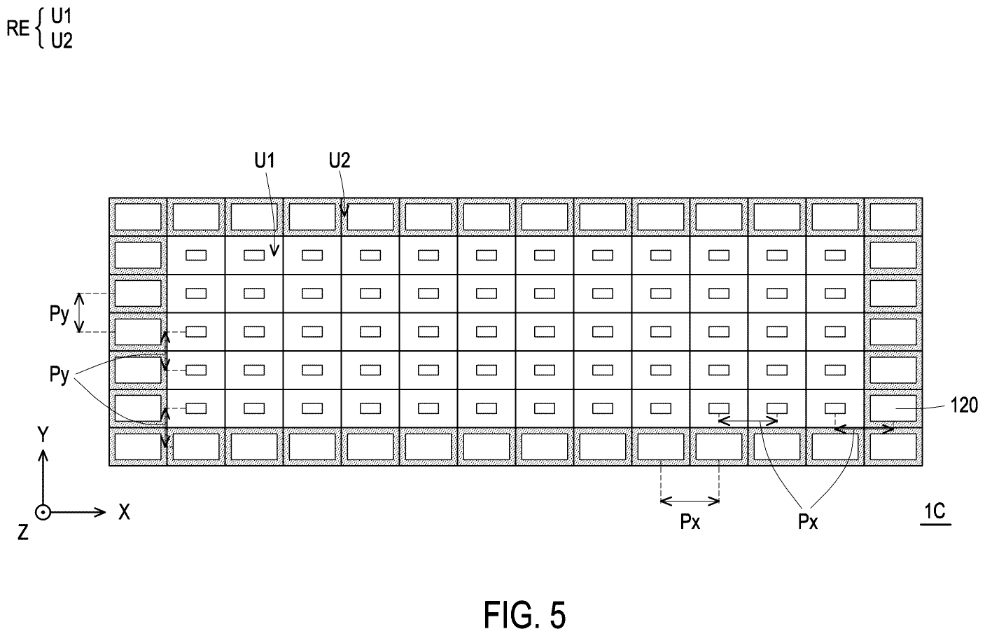

The density of light emitting diodes in the unit region may be changed by changing the number of light emitting diodes in the unit region, changing the size of the light emitting diodes in the unit region, or a combination of the above. Taking FIG. 3 as an example, the number of the light emitting diodes 120 of the second unit regions U2 may be greater than the number of the light emitting diodes 120 of the first unit region U1, so that the density of the light emitting diodes 120 in the second unit region U2 is greater than the density of the light emitting diodes 120 in the first unit region U1, but the disclosure is not limited thereto. As shown in FIG. 5, the size of the light emitting diode 120 of the second unit region U2 may be larger than the size of the light emitting diodes 120 in the first unit region U1, so that the density of the light emitting diodes 120 in the second unit region U2 is greater than the density of the light emitting diodes 120 in the first unit region U1.

In some embodiments, although not shown, the density of the light emitting diodes 120 positioned at the edge of the light emitting region may be further increased (for example, adjusting the quantity or size of the light emitting diode in the unit region) under the architecture that the edge of the light emitting region expands outward from the edge of the display region (as shown in FIG. 1) to further increase the brightness of the edge region. Alternatively, the density of the light emitting diodes 120 positioned at the edge of the light emitting region may be further increased under the architecture that the edge of the light emitting region is aligned with the edge of the display region or the edge of the light emitting region is reduced inward from the edge of the display region to further increase the brightness of the edge region.

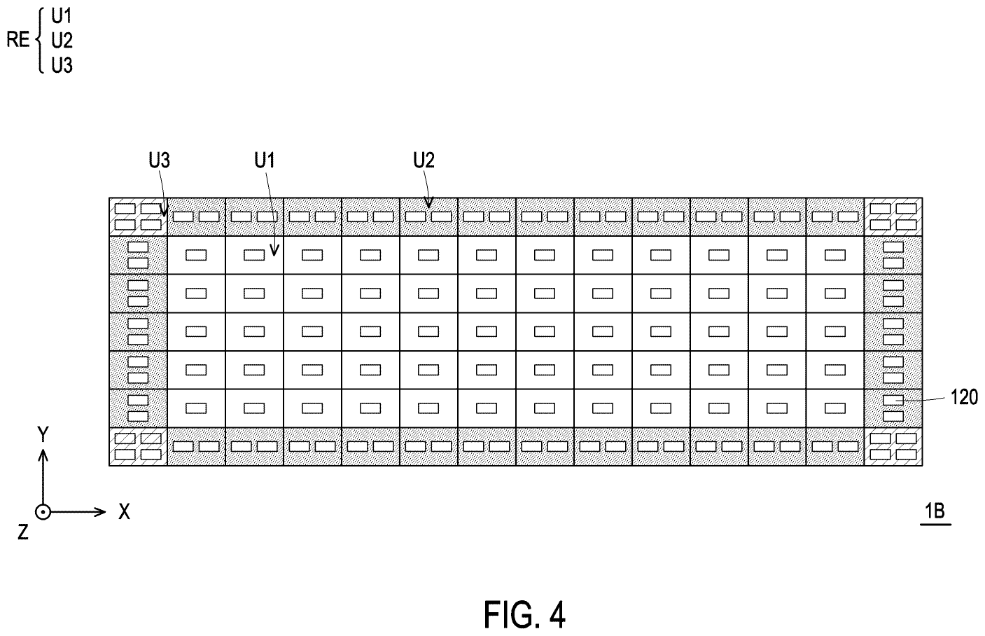

FIG. 4 is a schematic partial top view of a display device according to the third embodiment of the disclosure. For the brevity of the drawings, FIG. 4 only schematically shows the plurality of light emitting diodes 120 and omits other components. Please refer to FIG. 4. The main difference between a display device 1B and the display device 1A in FIG. 3 lies in the arrangement of the plurality of light emitting diodes 120.

In detail, in the display device 1B, the light emitting region RE also includes a plurality of third unit regions U3 (indicated by slash shading). An area of each of the plurality of third unit regions U3 may be equal to an area of each of the plurality of second unit regions U2 and an area of each of the plurality of first unit regions U1. The plurality of third unit regions U3 are respectively positioned at the four corners of the light emitting region RE, and a density of the light emitting diodes 120 of the third unit regions U3 is greater than the density of the light emitting diodes 120 of the second unit regions U2. As mentioned above, the density of light emitting diodes in the unit region may be changed by changing the size, the number of light emitting diodes in the unit region, or a combination of the above. FIG. 4 schematically shows that the number of the light emitting diodes 120 of the third unit regions U3 is greater than the number of the light emitting diodes 120 of the second unit regions U2, and the number of the light emitting diodes 120 in the second unit regions U2 is greater than the number of the light emitting diodes 120 in the first unit regions U1, but the method of changing the density of light emitting diodes in the unit region is not limited thereto.

By increasing the density of the light emitting diodes at the edge corners of the light emitting region RE, the brightness at the edge corners can be increased, which helps to improve the problem of surrounding dark regions or uneven brightness.

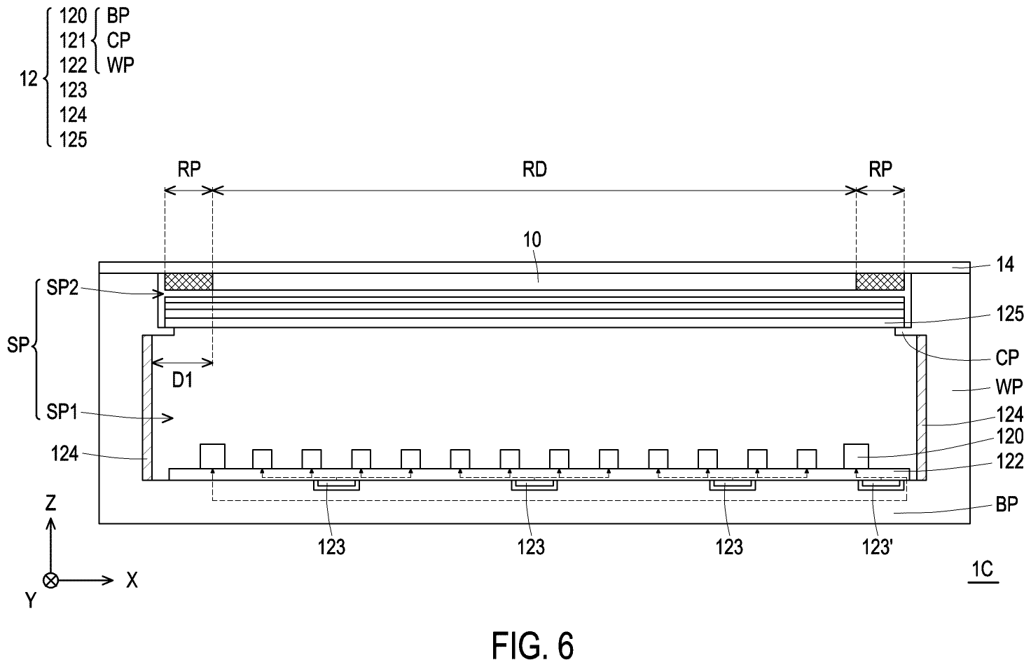

FIG. 5 and FIG. 6 are respectively a partial top view and a schematic cross-sectional view of a display device according to the fourth embodiment of the disclosure. Please refer to FIG. 5 and FIG. 6. The main differences between a display device 1C and the display device 1A in FIG. 3 are described below. In the display device 1C, by making the size of the light emitting diodes 120 of the second unit regions U2 larger than the size of the light emitting diodes 120 of the first unit regions U1, the density of the light emitting diodes 120 of the second unit regions U2 is greater than the density of the light emitting diodes 120 of the first unit regions U1.

In addition, pitches of the plurality of light emitting diodes 120 are the same. For example, the plurality of light emitting diodes 120 have the same pitch Px in the direction X, and the plurality of light emitting diodes 120 have the same pitch Py in the direction Y, but not limited thereto. Through the design of the plurality of light emitting diodes 120 having the same pitch can simplify the manufacturing process (such as bonding) or design (such as wiring).

In addition, the light emitting diodes 120 in the first unit regions U1 and the light emitting diodes 120 in the second unit regions U2 may be controlled by different chips respectively. For example, the plurality of light emitting diodes 120 positioned in the plurality of first unit region U1 may be controlled by the plurality of chips 123, and the plurality of light emitting diodes 120 positioned in the plurality of second unit region U2 may be controlled by a chip 123′, but not limited thereto. Through the design of the light emitting diodes in different unit regions being controlled by different chips, the brightness of the light emitting diodes in different unit regions may be independently controlled, and thus help improve the problem of surrounding dark regions or uneven brightness. Although not shown, under the architectures of FIG. 3 and FIG. 4, light emitting diodes positioned in different unit regions may also be controlled by different chips.

In summary, in the embodiments of the disclosure, by making the area of the light emitting region larger than the area of the display region, the brightness of the edge region can be increased, which helps to improve the problem of surrounding dark regions or uneven brightness. In some embodiments, by changing the density of the light emitting diodes in the unit region or through the design of the light emitting diodes in different unit regions being controlled by different chips, the problem of surrounding dark regions or uneven brightness can be further improved.

The above embodiments are only used to illustrate the technical solution of the disclosure, and the embodiments are not to limit the disclosure. Although the disclosure has been described in detail with reference to the above-mentioned embodiments, persons skilled in the art should understand that the technical solutions described in the above-mentioned embodiments may still be modified, or some or all of the technical features may be equivalently replaced. However, the modifications or replacements do not make the essence of the corresponding technical solutions depart from the scope of the technical solutions of the embodiments of the disclosure.

Although the embodiments of the disclosure and the advantages thereof have been disclosed above, it should be understood that persons with ordinary knowledge in the technical field may make changes, substitutions, and modifications without departing from the spirit and scope of the disclosure, and the features of each of the embodiments may be mixed and replaced with each other at will to form other new embodiments. In addition, the protection scope of the disclosure is not limited to the manufacturing process, machine, manufacturing, substance composition, device, method, and operations in the embodiments described in the specification, and persons with ordinary knowledge in the technical field may understand that the current or future development of the manufacturing process, machine, manufacturing, substance composition, device, method, and operations can be implemented based on this disclosure from the content of this disclosure as long as the same function can be substantially performed or the same results be substantially obtained in the embodiments described herein. Therefore, the protection scope of the disclosure includes the above-mentioned manufacturing process, machine, manufacturing, substance composition, device, method, and operations. In addition, each claim constitutes an individual embodiment, and the protection scope of the disclosure also includes combinations of the individual claims and the embodiments. The scope of protection of this disclosure should be defined by the appended claims.

What is claimed is:

1. A display device, comprising:
a display module having a display region; and
a backlight module overlapped with the display module and comprising a plurality of light emitting diodes;
wherein the plurality of light emitting diodes form a light emitting region, the light emitting region is overlapped with the display region, and an area of the light emitting region is larger than an area of the display region.

2. The display device according to claim 1, wherein a difference between a length of the light emitting region and a length of the display region is greater than 0 and smaller than or equal to 10 mm.

3. The display device according to claim 1, wherein the light emitting region comprises a plurality of first unit regions and a plurality of second unit regions, and an area of one of the plurality of first unit regions is equal to an area of one of the plurality of second unit regions, and a density of the light emitting diodes of one of the plurality of second unit regions is greater than a density of the light emitting diodes of one of the plurality of first unit regions.

4. The display device according to claim 3, wherein the plurality of second unit regions surround the plurality of first unit regions.

5. The display device according to claim 3, wherein the light emitting region further comprises a plurality of third unit regions, the plurality of third unit regions are respectively positioned at four corners of the light emitting region, and a density of the light emitting diodes of one of the plurality of third unit regions is greater than the density of the light emitting diode of one of the plurality of second unit regions.

6. The display device according to claim 5, wherein an area of one of the plurality of third unit regions is equal to an area of one of the plurality of second unit regions and an area of one of the plurality of first unit regions.

7. The display device according to claim 6, wherein the number of the light emitting diodes of one of the plurality of third unit regions is greater than the number of the light emitting diodes of one of the plurality of second unit regions.

8. The display device according to claim 7, wherein a size of the light emitting diode of one of the plurality of third unit regions is equal to a size of the light emitting diode of one of the plurality of second unit regions.

9. The display device according to claim 6, wherein a size of the light emitting diode of one of the plurality of third unit regions is larger than a size of the light emitting diode of one of the plurality of second unit regions.

10. The display device according to claim 9, wherein the number of the light emitting diodes in one of the plurality of third unit regions is equal to the number of the light emitting diodes of one of the plurality of second unit regions.

11. The display device according to claim 3, wherein the light emitting diodes in the plurality of first unit regions and the light emitting diodes in the plurality of second unit regions are controlled by different chips respectively.

12. The display device according to claim 3, wherein the number of the light emitting diodes of one of the plurality of second unit regions is greater than the number of the light emitting diodes of one of the plurality of first unit regions.

13. The display device according to claim 12, wherein a size of the light emitting diode of one of the plurality of second unit regions is equal to a size of the light emitting diode of one of the plurality of first unit regions.

14. The display device according to claim 3, wherein a size of the light emitting diode of one of the plurality of second unit regions is larger than a size of the light emitting diode of one of the plurality of first unit regions.

15. The display device according to claim 14, wherein the number of the light emitting diodes of one of the plurality of second unit regions is equal to the number of the light emitting diodes of one of the plurality of first unit regions.

16. The display device according to claim 1, wherein pitches of the plurality of light emitting diodes are the same.

17. The display device according to claim 1, wherein all of the display region falls within the light emitting region.

18. The display device according to claim 1, wherein the backlight module further comprises:
a back plate comprising a bottom portion, a side wall portion, and a carrying portion, wherein the plurality of light emitting diodes are disposed on the bottom portion, and the display module is disposed on the carrying portion; and
a reflection sheet disposed on the side wall portion.

19. The display device according to claim 18, wherein a maximum lateral distance between the reflection sheet and the display region of the display module is from 1 mm to 10 mm.

20. The display device according to claim 18, wherein the backlight module further comprises:
an optical film sheet disposed on the carrying portion and positioned between the display module and the plurality of light emitting diodes, wherein the optical film sheet maintains a light mixing distance with the plurality of light emitting diodes through the carrying portion.
